(19) United States
(12) Patent Application Publication
(10) Pub. No.: US 2021/0242025 A1
(43) Pub. Date: Aug. 5, 2021

(54) SILICIDATION OF SOURCE/DRAIN REGION OF VERTICAL FIELD EFFECT TRANSISTOR (VFET) STRUCTURE

(71) Applicant: SAMSUNG ELECTRONICS CO., LTD., Suwon-si (KR)

(72) Inventors: Min Gyu Kim, Hwaseong-si (KR); Hwi Chan Jun, Yongin-si (KR)

(73) Assignee: SAMSUNG ELECTRONICS CO., LTD., Suwon-si (KR)

(21) Appl. No.: 17/026,532

(22) Filed: Sep. 21, 2020

Related U.S. Application Data
(60) Provisional application No. 62/970,432, filed on Feb. 5, 2020.

(51) Int. Cl. H01L 21/285; H01L 29/78; H01L 29/06; H01L 29/08; H01L 29/45; H01L 29/66

(52) U.S. Cl. CPC H01L 21/28518; H01L 29/7827; H01L 29/66666; H01L 29/0847; H01L 29/45; H01L 29/0653

(57) ABSTRACT

A vertical field effect transistor (VFET) structure includes: a substrate; fin structures formed on the substrate; bottom source/drain regions formed on the substrate between and at opposite sides of lower portions of the fin structures; and shallow trench isolation (STI) structures formed at sides of the substrate and the bottom source/drain regions, wherein upper portions of the bottom source/drain regions include silicide layers each of which has a bar shape.

### CROSS-REFERENCE TO THE RELATED APPLICATION

This application claims priority from U.S. Provisional Application No. 62/970,432 filed on Feb. 5, 2020 in the U.S. Patent and Trademark Office, the disclosure of which is incorporated herein in its entirety by reference.

### BACKGROUND

### 1. Field

Apparatuses and methods consistent with exemplary embodiments of the inventive concept relate to structure of a vertical field effect transistor (VFET) and manufacturing of the same.

### 2. Description of the Related Art

A VFET is manufactured by forming a vertical fin, used for a channel for current flow, on a semiconductor substrate, a bottom source/drain region and a top source/drain region therebelow and on the vertical fin, and a gate structure on a sidewall of the vertical fin. Thus, a current flows in the VFET in a direction perpendicular to the semiconductor substrate unlike a lateral current flow in the related art planar FET or finFET.

Further, for connection of the VFET with another VFET, a power source or another electronic component, contact structures may be formed on the bottom source/drain region and the top source/drain region. However, the bottom source/drain region generally has an inherent contact resistance affecting against current flow through the VFET. This contact resistance may be reduced by siliciding an upper portion of the bottom source/drain region using a metal material such as cobalt, titanium or tungsten having high thermal stability. In a related art, the silicidation is performed on the bottom source/drain region after a shallow trench isolation (STI) structure is formed at sides of a VFET structure to insulate the VFET structure from another VFET structure or circuit elements.

FIGS. 1A and 1B illustrates cross-sectional side views of part of a process manufacturing a VFET device including a silicidation step according to a related art.

FIG. 1A shows an intermediate VFET structure 10 before silicidation is performed. The intermediate VFET structure 10 includes a substrate 100 and a plurality of fin structures 111 and 112 formed thereon. Each of the fin structures 111 and 112 includes a fin and a hard mask formed thereon. The intermediate VFET structure 10 also includes a bottom source/drain region 121 formed on the substrate 100 at a left side of a lower portion of the fin structure 111, a bottom source/drain region 122 formed on the substrate 100 at a right side of a lower portion of the fin structure 112, and a bottom source/drain region 123 formed on the substrate 100 between the lower portions of the fin structures 111 and 112. The intermediate VFET structure 10 further includes STI structures 131 and 132 respectively formed on left side surfaces of the substrate 100 and the bottom source/drain region 121, substantially coplanar with each other, and right side surfaces of the substrate 100 and the bottom source/drain region 122 substantially coplanar with each other.

Referring to FIG. 1B, after the STI structures 131 and 132 are formed as shown in FIG. 1A, upper portions of the STI structures 131 and 132 are etched to expose the left side of the bottom source/drain region 121 and the right side of the bottom source/drain region 122 facing the STI structures 131 and 132, respectively, before the etching, and then, silicidation is performed on the bottom source/drain regions 121 through 123 so that silicide layers 141 through 143 are formed in the bottom source/drain regions 121 through 123, respectively. It is noted here that the silicide layer 141 and 142 are formed not only at upper portions of the bottom source/drain regions 121 and 122 but also at a left side portion of the bottom source/drain region 121 and a right side portion of the bottom source/drain region 122, while the silicide layer 143 is formed only at an upper portion of the bottom source/drain region 123. Thus, the silicide layers 141 and 142 have an L shape, while the silicide layer 143 has a bar shape.

However, this method of silicidation results in loss of the STI structures and loss of a bottom spacer to be formed on the bottom source/drain regions 121 through 123 in a later step because the silicidation is performed after the STI structures 131 and 132 are formed and the upper portions thereof are etched. In addition, this method of silicidation is complicated due to the etching step performed on the STI structures 131 and 132 to expose the left and right side surfaces of the bottom source/drain regions 121 and 122, respectively.

Thus, an improved method of siliciding a bottom source/drain region of a VFET structure is required.

### SUMMARY

Various embodiments of the inventive concept may provide an improved method for manufacturing a VFET structure and the VFET structure manufactured thereby.

According to an aspect of an exemplary embodiment, there is provided a VFET structure that may include: a substrate; fin structures formed on the substrate; bottom source/drain regions formed on the substrate between and at opposite sides of lower portions of the fin structures; and shallow trench isolation (STI) structures formed at sides of the substrate and the bottom source/drain regions, wherein upper portions of the bottom source/drain regions include bottom silicide layers each of which has a bar shape:

According to an aspect of an exemplary embodiment, there is provided a VFET structure that may include: a substrate; fin structures formed on the substrate; bottom source/drain regions formed on the substrate between and at opposite sides of lower portions of the fin structures; shallow trench isolation (STI) structures formed at sides of the substrate and the bottom source/drain regions; and top source/drain regions formed on the fin structures, respectively, wherein upper portions of the top source/drain regions include top silicide layers, respectively.

According to an aspect of an exemplary embodiment, there is provided a method for manufacturing a VFET structure that may include: providing an intermediate VFET structure comprising a substrate, and fin structures and bottom source/drain regions on the substrate at opposite sides of lower portions of the fin structures; siliciding upper portions of the bottom source/drain regions so that bottom silicide layers are formed at upper portions of the bottom source/drain regions; and forming shallow trench isolation (STI) structures at sides of the substrate and the bottom source/drain regions of which the upper portions are silicided, wherein each of the bottom silicide layers has a bar shape.

### BRIEF DESCRIPTION OF THE DRAWINGS

The above and other aspects of inventive concepts will become more apparent to those of ordinary skill in the art by describing in detail example embodiments thereof with reference to the accompanying drawings, in which:

FIGS. 1A and 1B illustrates cross-sectional side views of part of a process manufacturing a VFET device including a silicidation step according to a related art;

FIGS. 2A through 2G illustrate cross-sectional side views of part of a process manufacturing a VFET device including a silicidation step according to an embodiment; and

FIGS. 3A through 3D illustrate cross-sectional side views of part of a process manufacturing a VFET device including a silicidation step according to an embodiment.

### DETAILED DESCRIPTION

Various embodiments of the inventive concept will be described more fully hereinafter with reference to the accompanying drawings. These embodiments are all exemplary, and may be embodied in many different forms and should not be construed as limiting the inventive concept. Rather, these embodiments are merely provided so that this disclosure will be thorough and complete, and will fully convey the inventive concept to those skilled in the art. The inventive concept may be defined by the scope of the appended claims. In the drawings, the sizes and relative sizes of the various layers and regions may have been exaggerated for clarity, and thus, the drawings are not necessarily to scale, some features may be exaggerated to show details of particular components or elements. Therefore, specific structural and functional details disclosed herein are not to be interpreted as limiting, but merely as a representative basis for teaching one skilled in the art to variously employ the methods and structures of the embodiments.

An embodiment provided herein is not excluded from being associated with one or more features of another example or another embodiment also provided herein or not provided herein but consistent with the inventive concept. For example, even if matters described in a specific embodiment are not described in a different embodiment, the matters may be understood as being related to or combined with the different embodiment, unless otherwise mentioned in descriptions thereof.

For the purposes of the description hereinafter, the terms “upper”, “lower”, “top”, “bottom”, “left,” and “right,” and derivatives thereof can relate, based on context, to the disclosed structures, as they are oriented in the drawings. The same numbers in different drawings may refer to the same structural component or element thereof.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It will be also understood that the layers, patterns, regions and/or elements shown in the accompanying drawings are not drawn to scale, and one or more commonly-used layers, patterns, regions and/or elements in typical semiconductor devices may not be explicitly shown in the drawings. This does not mean that those layers, patterns, regions and/or elements are not included in actual semiconductor devices corresponding to the embodiments described herein, and instead, those layers, patterns and/or regions may be omitted from the drawings only for the sake of clarity and/or brevity when explanations are not necessarily focused thereon.

As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “A, B, and/or C” means either A, B, C or any combination thereof. Expressions such as “at least one of,” when preceding a list of elements, modify the entire list of elements and do not modify the individual elements of the list.

Unless otherwise defined, all terms (including technical and scientific terms) used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

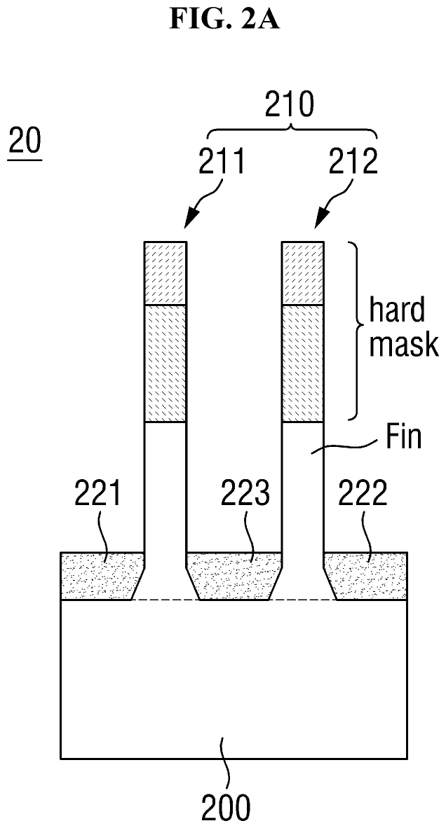

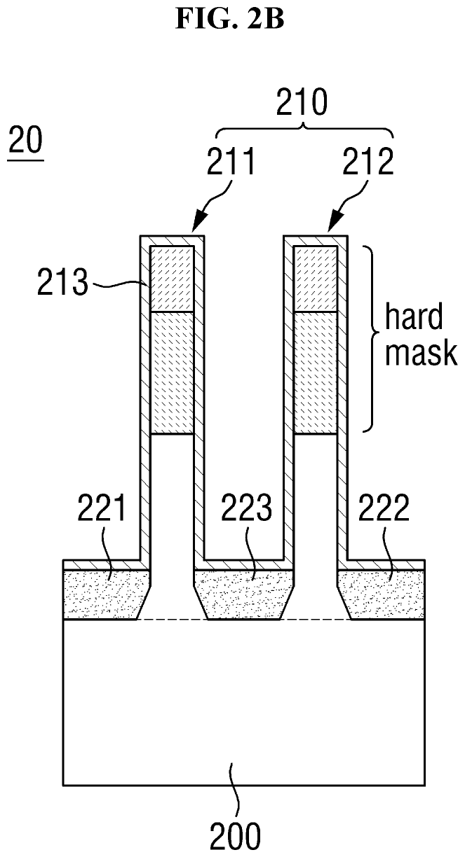

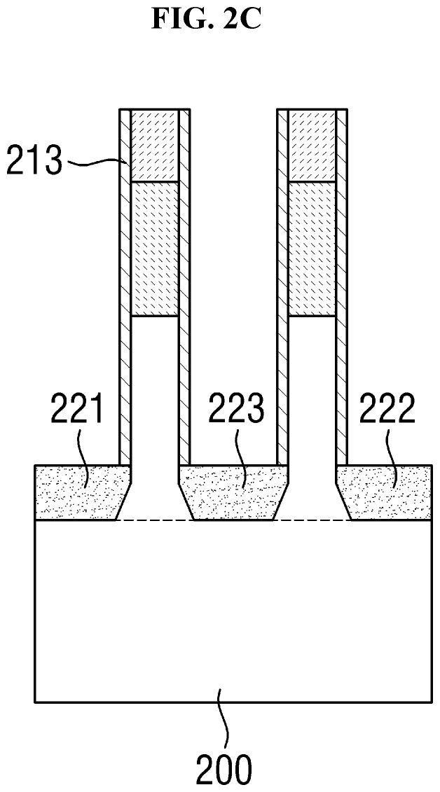

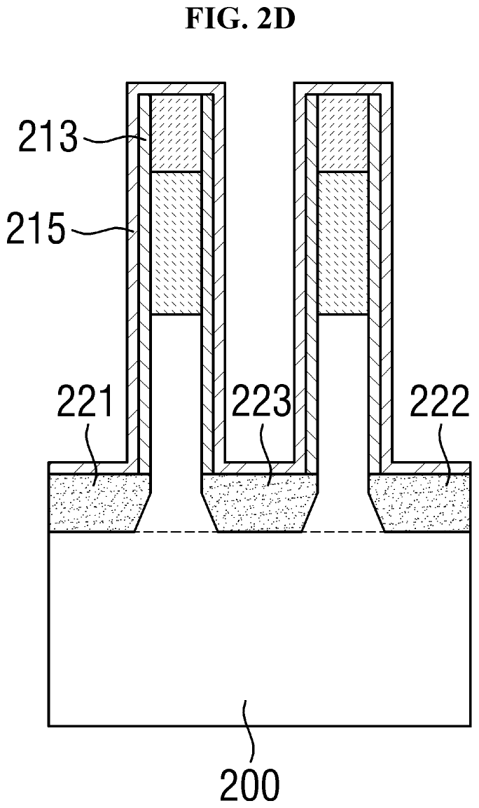

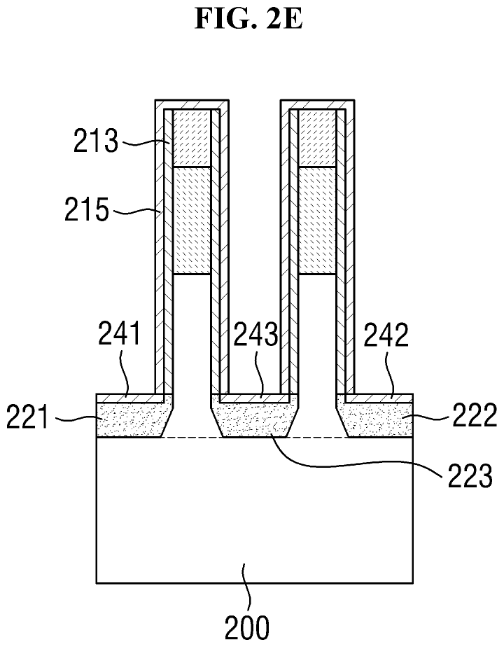

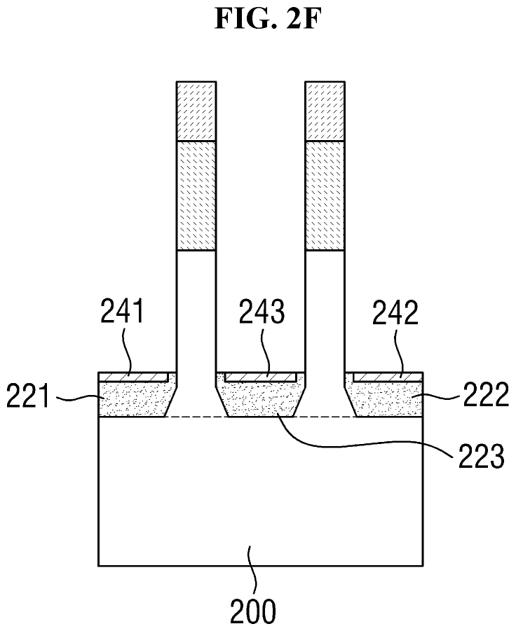

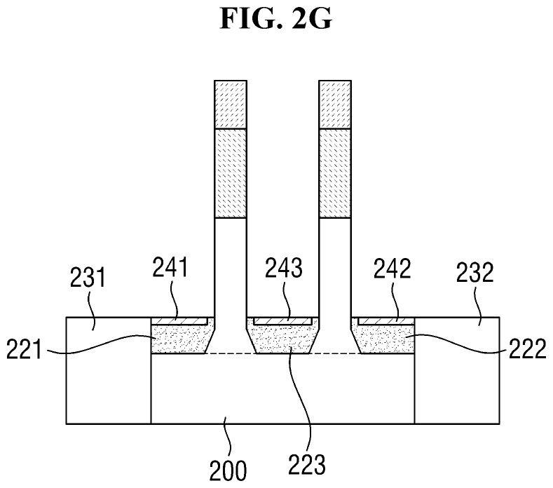

FIGS. 2A through 2G illustrate cross-sectional side views of part of a process manufacturing a VFET device including a silicidation step according to an embodiment.

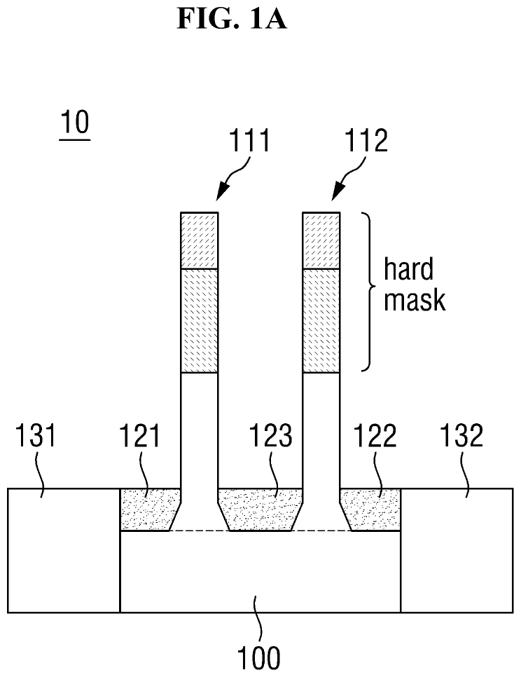

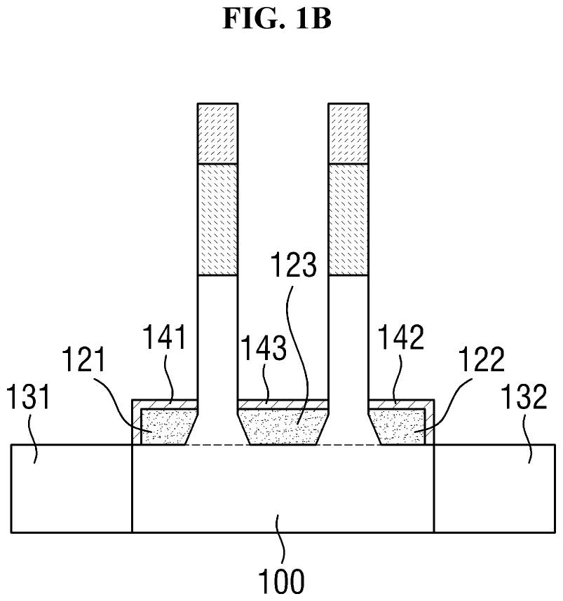

FIG. 2A shows an intermediate VFET structure 20 before silicidation is performed according to an embodiment. Similar to the intermediate VFET structure 10 in FIG. 1A, the intermediate VFET structure 20 includes a substrate 200 and a plurality of fin structures 211 and 212 formed thereon, and each of the fin structures 211 and 212 includes a fin and a hard mask formed thereon. The intermediate VFET structure 20 also includes a bottom source/drain region 221 formed on the substrate 200 at a left side of a lower portion of the fin structure 211, a bottom source/drain region 222 formed on the substrate 200 at a right side of a lower portion of the fin structure 212, and a bottom source/drain region 223 formed on the substrate 200 between the lower portions of the fin structures 211 and 212. Left side surfaces of the bottom source/drain region 221 and the substrate 200 may be substantially coplanar with each other, and right side surfaces of the bottom source/drain region 222 and the substrate 200 may be substantially coplanar with each other.

In the intermediate VFET structure 20, the substrate 200 may be formed of one or more layers including a semiconductor material including silicon (Si), silicon germanium (SiGe), silicon carbide (SiC), and/or silicon-germanium-carbon (SiGeC), not being limited thereto, and the fin of each of the fin structures 211 and 212 may be formed of a material such as silicon (Si), germanium (Ge), silicon germanium (SiGe), and/or a silicon-containing material, not being limited thereto. The hard mask formed on each of the fin structures 211 and 212 is used for patterning a semiconductor layer to form the fin on the substrate 200, and may be formed of a dielectric material such as silicon nitride (SiN) or a combination of an SiN mask and an oxide mask formed thereon. The bottom source/drain regions 221 through 223 may have been epitaxially grown on the substrate 200 and doped with impurities which may include boron or its combination to form a p-type VFET, or phosphorus, arsenic, indium or their combination to form an n-type VFET, when the intermediate VFET structure 20 is finished to a VFET device.

FIGS. 2B and 2C show that a protection layer 213 is deposited to cover the fin structures 211 and 212 and top surfaces of the bottom source/drain regions 221 through 223, and then, the protection layer 213 on top surfaces of the fin structures 211 and 212 and the top surfaces of the bottom source/drain regions 221 through 223 are removed to leave the protection layer 213 only on side surfaces of the fin structures 211 and 212 to protect the fin structures 210 from silicidation to be performed in a next step. Here, the removal of the protection layer 213 from the top surfaces of the fin structures 211 and 212 and the top surfaces of the bottom source/drain regions 221 through 223 may be performed by anisotropic etching, ion beam etching, plasma etching and/or laser ablation, not being limited thereto. The protection layer 213 may be formed of silicon dioxide (SiO₂), silicon nitride (SiN), silicon boron carbonitride (SiBCN), silicon oxycarbonitride (SiOCN), or their combination thereof, not being limited thereto.

FIG. 2D shows that a metal material such as cobalt, titanium and tungsten having high thermal stability is deposited on the fin structures 210 to form a metal layer 215 enclosing the fin structures 210, of which the side surfaces are covered by the protection layer 213, and the top surfaces of the bottom source/drain regions 221 through 223. Thus, the metal layer 215 is formed on the top surfaces of the fin structures 211 and 212, top and side surfaces of the protection layer 213, and the top surfaces of the bottom source/drain regions 221 through 223. Here, the deposition of the metal material to form the metal layer 214 may be performed by chemical vapor deposition (CVD), plasma-enhanced VD (PEVD), physical vapor deposition (PVD), atomic layer deposition (ALD), plasma-enhanced ALD (PEALD), anisotropic deposition, sputtering, and/or plating, not being limited thereto.

FIG. 2E shows that the metal layer 215 is annealed at a high temperature range between about 300° C. and about 700° C. so that the metal layer 215 reacts with silicon components included in upper portions of the bottom source/drain region 221 through 223 to form bottom silicide layers 241 through 243, including at least one of CoSiₓ, TiSiₓ and/or WSiₓ therein, at the upper portions of the bottom source/drain region 221 through 223, respectively.

FIG. 2F shows that, after the silicidation of the metal layer 215 at the upper portions of the bottom source/drain regions 221 through 223, the protection layer 213 and the metal layer 215 formed thereon are stripped, for example, by etching such as dry etching, not being limited thereto.

FIG. 2G shows that STI structures 231 and 232 similar to the STI structures 131 and 132 shown in FIG. 1B are formed at the left and right side surfaces of the intermediate VFET structure 20 to isolate the intermediate VFET structure 20 from another intermediate VFET structure or circuit element. The STI structures 231 and 232 may be formed of a dielectric oxide material such as silicon oxide (SiO), SiO₂, silicon oxynitride (SiOₓN_{y}) or their combination, not being limited thereto.

Referring to FIG. 2G in view of FIG. 1B, all of the bottom silicide layers 241 through 243 respectively formed at the upper portions of the bottom source/drain region 221 through 223 have substantially a bar shape, while the silicide layers 141 through 143 respectively formed at the upper portions of the bottom source/drain region 121 through 123 according to the related art have a bar shape and an L shape. Further, top surfaces of the STI structures 231 and 232 are substantially coplanar with top surfaces of the bottom silicide layers 241 through 243, that is, top surfaces of the bottom source/drain regions 221 through 223 of which the upper portions are silicided, while top surfaces of the STI structures 131 and 132 are at a level lower than a level of top surfaces of the silicide layers 141 through 143, that is, top surfaces of the bottom source/drain regions 121 through 123 of which the upper portions are silicided. These differences are caused by improving the silicidation process of the related art by forming STI structures at side surfaces of a VFET structure after siliciding upper portions of bottom source/drain regions of the VFET structure. By this process improvement, it is possible to prevent loss of STI structures and loss of a bottom spacer to be formed on the bottom source/drain regions of the VFET structure in a later step. Further, the process of forming the VFET structure may be simplified by omitting a step of etching upper portions of the STI structures before siliciding the bottom source/drain regions.

In the above embodiment, silicidation is performed on bottom source/drain regions of a VFET structure. However, silicidation may also be performed on top source/drain regions of the VFET structure according to an embodiment as described below.

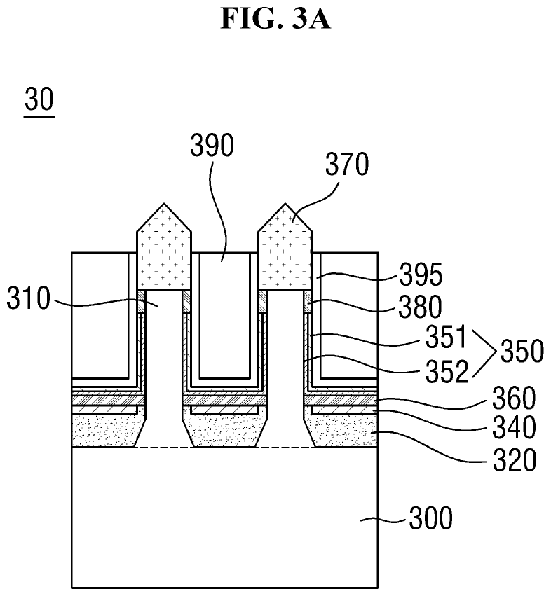

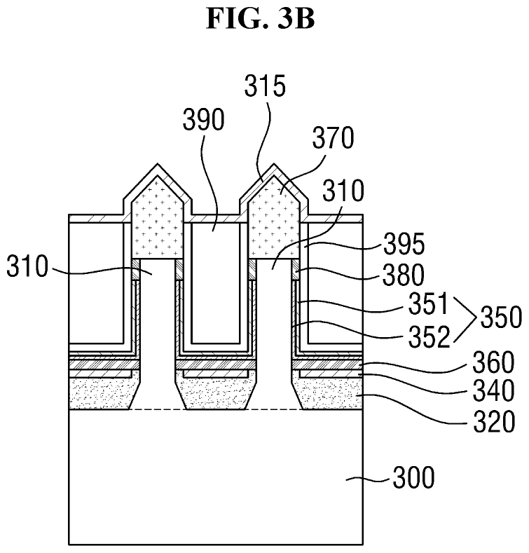

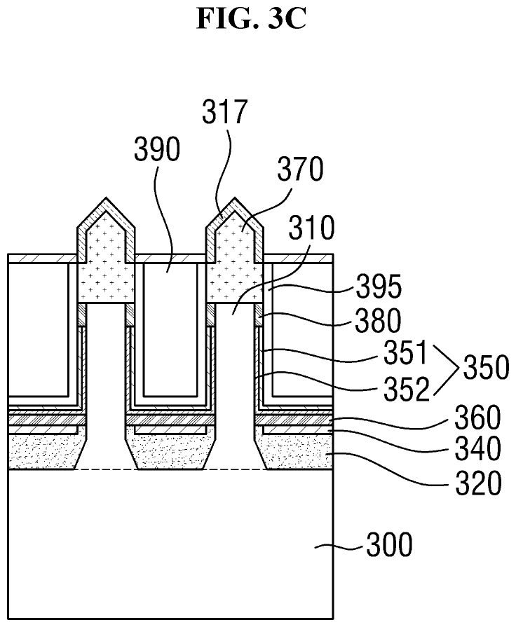

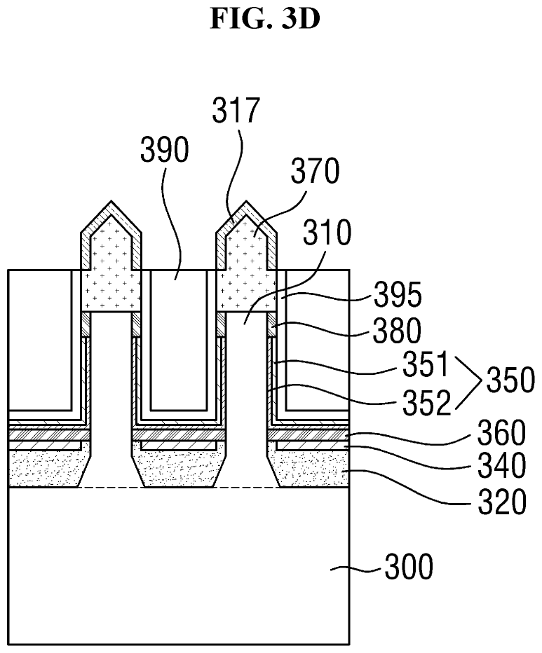

FIGS. 3A through 3D illustrate cross-sectional side views of part of a process manufacturing a VFET device including a silicidation step according to an embodiment.

FIG. 3A shows an intermediate VFET structure 30 in which fin structures 310, bottom source/drain regions 320 including bottom silicide layers 340, and top source/drain regions 370 are formed above a substrate 300. The intermediate VFET structure 30 also includes gate structures 350 formed on the fin structures 310, bottom spacers 360 formed on top surfaces of the bottom source/drain regions 320 to insulate the bottom source/drain regions 320 from the gate structures 350, and top spacers 380 formed on the gate structures 350 to insulate the top source/drain regions 370 from the gate structures 350. Between and at sides of the gate structures 350, interlayer dielectric (ILD) layers 390 are filled in to insulate the gate structures 350 from one another.

The materials and methods of forming the substrate 300, the fin structures 310, the bottom source/drain regions 320, and the bottom silicide layers 340 are the same or similar to the substrate 200, the fin structures 210, the bottom source/drain regions 221 through 223, and the bottom silicide layer 241 through 243, and thus, description thereabout are omitted herein.

Each of the gate structures 350 includes a conductor layer 351 formed of a metal or metal compound such as Cu, Al, Ti, Ta, W, Co, TiN, WN, TiAl, TiAlN, TaN, TiC, TaC, TiAlC, TaCN, TaSiN, or a combination thereof, not being limited thereto, and a high-κ layer 352 formed of a metal oxide material or a metal silicate such as Hf, Al, Zr, La, Mg, Ba, Ti, Pb, or a combination thereof, not being limited thereto. The bottom spacers 360 may include a low-κ dielectric material such as SiO, SiN, silicon oxynitride (SiON), carbon-doped silicon nitride (SiCN), silicon oxynitride (SiON), SiBCN, SiOCN, or combinations thereof, not being limited thereto. The bottom spacers 360 may be formed on the bottom source/drain regions 320 by at least one of methods such as CVD, PEVD, PVD, ALD, PEALD, anisotropic deposition, etc., not being limited thereto.

The top source/drain regions 370 may be formed by epitaxially growing a semiconductor layer on the fin structures 310 from which the masks (shown in FIG. 2G) are removed, and doping impurities therein. The top spacers 380 may be formed of a material similar to or different from the material forming the bottom spacer 360 by a method similar to the method used to form the bottoms spacers 360.

The ILD layers 390 may be formed of a material including SiO₂, Si₃N₄, SiOₓN_{y}, SiC, SiCO, SiCOH or SiCH compounds or their combinations, not being limited thereto. The ILD layers 390 may be formed by depositing a material including nitride, oxide, or a combination thereof, not being limited thereto, on ILD liners 395 which may be formed of a material such as SiN.

FIG. 3B shows that a metal layer 315 which is the same as or similar to the metal layer 215 shown in FIGS. 2D and 2E is formed on top surfaces of the top source/drain regions 370 and top surfaces of the ILD layers 390 by CVD, PEVD, PVD, ALD, PEALD, anisotropic deposition, sputtering, and/or plating, not being limited thereto. The metal layer 315 may include at least one of cobalt, titanium and tungsten having high thermal stability as described in the previous embodiment. According to an embodiment, the metal layer 315 may be deposited on substantially all outer surfaces of the top source/drain regions 370 protruded from the ILD layers 390 and the top surfaces of the ILD layers 390.

FIG. 3C shows that the metal layer 315 is annealed at a high temperature range between about 300° C. to about 700° C. so that the metal layer 315 reacts with silicon components included in upper portions of the top source/drain regions 370 to form top silicide layers 317 at upper portions of the top source/drain region 370, respectively.

FIG. 3D shows that portions of the metal layer 315 which are not silicided may be stripped, for example, by etching such as dry etching, not being limited thereto, and thus, the top silicide layers 317 remain only on the top surfaces of the top source/drain regions 370. According to an embodiment, the top silicide layer 317 may cover substantially all outer surfaces of the top source/drain regions 370 protruded from the ILD layers 390 to increase an area of reduced contact resistance.

According to the present embodiment, the silicidation is performed not only on the bottom source/drain regions but also on the top source/drain regions of a VFET structure, and thus, contact resistance is reduced at both of the bottom source/drain regions and the top source/drain regions to improve performance of a VFET device finished from the VFET structure.

The VFET structures and methods for forming the same in accordance with the above embodiments can be employed in applications, hardware, and/or electronic systems. Suitable hardware and systems for implementing embodiments of the inventive concept may include, but are not limited to, personal computers, communication networks, electronic commerce systems, portable communications devices (e.g., cell and smart phones), solid-state media storage devices, functional circuitry, etc. Systems and hardware incorporating the VFET structures according to the above embodiments are contemplated embodiments of the invention. Given the teachings of the above embodiments, one of ordinary skill in the art will be able to contemplate other implementations and applications of the embodiments.

The foregoing is illustrative of exemplary embodiments and is not to be construed as limiting thereof. For example, one or more steps described above for manufacturing a VFET device may be omitted to simplify the process. Although a few exemplary embodiments have been described, those skilled in the art will readily appreciate that many modifications are possible in the above embodiments without materially departing from the inventive concept.

What is claimed is:

1. A vertical field effect transistor (VFET) structure comprising:
a substrate;
fin structures formed on the substrate;
bottom source/drain regions formed on the substrate between and at opposite sides of lower portions of the fin structures; and
shallow trench isolation (STI) structures formed at sides of the substrate and the bottom source/drain regions,
wherein upper portions of the bottom source/drain regions comprise bottom silicide layers each of which has a bar shape.

2. The VFET structure of claim 1, wherein the bottom source/drain regions comprise:
a first bottom source/drain region formed on the substrate between the lower portions of the fin structures; and
a second bottom source/drain region formed on the substrate at a left side of a lower portion of one of the fin structures, and
wherein a top surface of an upper portion of the second bottom source/drain region comprising one of the bottom silicide layers is substantially coplanar with a top surface of one of the STI structures facing the substrate and the second bottom source/drain region.

3. The VFET structure of claim 2, wherein the bottom source/drain regions further comprising a third bottom source/drain region formed on the substrate and at a right side of a lower portion of another one of the fin structures, and
wherein a top surface of an upper portion of the third bottom source/drain region comprising another one of the bottom silicide layers is substantially coplanar with a top surface of another one of the STI structures facing the substrate and the third bottom source/drain region.

4. The VFET structure of claim 1, wherein top surfaces of the STI structures and top surfaces of the upper portions of the bottom source/drain regions are substantially coplanar with one another.

5. The VFET structure of claim 1, wherein each of the bottom silicide layers is formed of at least one of cobalt silicide (CoSiₓ), titanium silicide (TiSiₓ) or tungsten silicide (WSiₓ).

6. The VFET structure of claim 1, further comprising top source/drain regions formed on the fin structures, respectively,
wherein upper portions of the top source/drain regions comprise top silicide layers, respectively.

7. The VFET structure of claim 6, further comprising interlayer dielectric (ILD) layers between and at sides of the fin structures,
wherein portions of the top source/drain regions are protruded from the ILD layers, and
wherein the top silicide layers cover substantially all outer surfaces of the top source/drain region protruded from the ILD layers.

8. The VFET structure of claim 6, wherein each of the top silicide layers is formed of at least one of cobalt silicide (CoSiₓ), titanium silicide (TiSiₓ) and tungsten silicide (WSiₓ).

9. A vertical field effect transistor (VFET) structure comprising:
a substrate;
fin structures formed on the substrate;
bottom source/drain regions formed on the substrate between and at opposite sides of lower portions of the fin structures;
shallow trench isolation (STI) structures formed at sides of the substrate and the bottom source/drain regions; and
top source/drain regions formed on the fin structures, respectively,
wherein upper portions of the top source/drain regions comprise top silicide layers, respectively.

10. The VFET structure of claim 9, further comprising interlayer dielectric (ILD) layers between and at sides of the fin structures,
wherein portions of the top source/drain regions are protruded from the ILD layers, and
wherein the top silicide layers cover substantially all outer surfaces of the top source/drain region protruded from the ILD layers.

11. The VFET structure of claim 10, wherein upper portions of the bottom source/drain regions comprise bottom silicide layers each of which has a bar shape.

12. The VFET structure of claim 11, wherein each of the bottom and top silicide layers is formed of at least one of cobalt silicide (CoSiₓ), titanium silicide (TiSiₓ) and tungsten silicide (WSiₓ).

13. A method for manufacturing a vertical field effect transistor (VFET) structure, the method comprising:
providing an intermediate VFET structure comprising a substrate, and fin structures and bottom source/drain regions on the substrate at opposite sides of lower portions of the fin structures;
siliciding upper portions of the bottom source/drain regions so that bottom silicide layers are formed at upper portions of the bottom source/drain regions; and
forming shallow trench isolation (STI) structures at sides of the substrate and the bottom source/drain regions of which the upper portions are silicided,
wherein each of the bottom silicide layers has a bar shape.

14. The method of claim 13, wherein the siliciding the upper portions of the bottom source/drain regions comprises:
forming a metal layer on top and side surfaces of the fin structures and top surfaces of the bottom source/drain regions;
annealing the metal layer at predetermined high temperature so that the metal layer at the upper portions of the bottom source/drain regions change to the bottom silicide layers; and
removing the metal layer from the top and side surfaces of the fin structures.

15. The method of claim 14, wherein the metal layer comprises at least one of cobalt, titanium and tungsten.

16. The method of claim 14, wherein the siliciding the upper portions of the bottom source/drain regions comprises:
forming protection layers on the side surfaces of the fin structures before the metal layer is formed on the top and side surfaces of the fin structures so that the metal layer formed on the side surfaces of the fin structures is formed on side surfaces of the protection layers; and
removing the protection layers with the metal layer from the side surfaces of the fin structures after the metal layer is annealed.

17. The method of claim 13, wherein the forming the STI structures is performed such that top surfaces of the STI structures and top surfaces of the upper portions of the bottom source/drain regions are substantially coplanar with one another.

18. The method of claim 13, further comprising:
forming top source/drain regions on the fin structures, respectively;
forming interlayer dielectric (ILD) layers between and at sides of the fin structures; and
siliciding upper portions of the top source/drain region so that top silicide layers are formed at the upper portions of the top source/drain regions, respectively.

19. The method of claim 18, wherein the siliciding the upper portions of the top source/drain regions comprises:
forming a metal layer on top surfaces of the top source/drain regions protruded from the ILD layers and top surfaces of the ILD layers;
annealing the metal layer; and
removing the metal layer from the top surfaces of the ILD layers,
wherein the metal layer comprises at least one of cobalt, titanium and tungsten.

20. The method of claim 18, wherein the siliciding the upper portions of the top source/drain regions is performed such that the top silicide layers are formed on substantially all outer surfaces of the top source/drain regions protruded from the ILD layers.
